(19) United States
(12) Patent Application Publication
(10) Pub. No.: US 2009/0223560 A1
(43) Pub. Date: Sep. 10, 2009

(54) SOLAR CELL AND METHOD FOR MANUFACTURING THE SAME

(76) Inventor: Dae-Won Kim, Yongin-si (KR)

Correspondence Address: CHRISTIE, PARKER & HALE, LLP, PO BOX 7068, PASADENA, CA, 91109-7068, US

(21) Appl. No.: 12/105,221

(22) Filed: Apr. 17, 2008

(30) Foreign Application Priority Data
Mar. 4, 2008 (KR) 10-2008-0020123

(51) Int. Cl. H01L 31/0216; H01L 31/18

(52) U.S. Cl. 136/256; 438/72; 257/E31.121

(57) ABSTRACT

A solar cell, including: a semiconductor substrate of a first conductive type, the semiconductor substrate having a first surface and a second surface facing away from to each other; a first electrode electrically coupled to the first surface of the semiconductor substrate; an emitter portion of a second conductive type, the emitter portion being adjacent to the second surface of the semiconductor substrate; an anti-reflective layer on the emitter portion and including a transparent electrode; and a second electrode on the anti-reflective layer and electrically coupled to the emitter portion through the anti-reflective layer, wherein the anti-reflective layer has a refractive index that is not less than 1.5 in a spectrum ranging from about 400 nm to about 1000 nm, and wherein the anti-reflective layer has a sheet resistance that is not greater than that of the emitter portion.

### CROSS-REFERENCE TO RELATED APPLICATION

This application claims priority to and the benefit of Korean Patent Application No. 10-2008-0020123, filed in the Korean Intellectual Property Office on Mar. 4, 2008, the entire content of which is incorporated herein by reference.

### BACKGROUND OF THE INVENTION

1. Field of the Invention

The present invention relates to a solar cell and a method for manufacturing the same. More particularly, the present invention relates to a solar cell having an anti-reflective layer, and a method for manufacturing the same.

2. Description of the Related Art

A solar cell generates electrical energy from solar energy. The solar cell is environmentally friendly, and its energy source is substantially endless. In addition, the solar cell has a long lifespan. Examples of the solar cell include a semiconductor solar cell and a dye-sensitized solar cell as devices to generate electrical energy from solar energy.

In the semiconductor solar cell, a base and an emitter portion, which are of different conductive types, are formed on a semiconductor substrate to form a p-n junction. Front electrodes are formed on the emitter portion, and rear electrodes are formed on a rear surface of the semiconductor substrate (facing away from the front electrodes). An anti-reflective layer is formed on a front surface of the semiconductor substrate (facing away from the rear electrodes) where the emitter portion is formed, to prevent (or reduce) incident light from reflecting at the front surface thereof.

Generally, the anti-reflective layer is formed of silicon nitride (SiNₓ) that has an excellent (or suitable) refractive index. However, since the anti-reflective layer of the silicon nitride is not conductive, a firing through process is necessary to electrically connect the front electrodes and the semiconductor substrate.

In more detail, according to the conventional method for manufacturing a solar cell, a paste for forming rear electrodes is applied after the anti-reflective layer is formed on the front surface of the semiconductor substrate where the emitter portion is located. In order to electrically connect the front electrodes to the emitter portion, the paste etches the anti-reflective layer in the firing through process that is generated at a high temperature.

If the firing through process is excessively generated, then a shunt may be formed. On the other hand, if the firing through process is not generated fully, then the front electrodes are not electrically connected to the emitter portion. Accordingly, an amount of the firing through must be precisely controlled to connect the front electrodes to the emitter portion. Thus, the manufacturing process can be complicated.

In addition, the firing though process is induced at a high temperature, so the solar cell can be damaged by the heat treatment.

To solve the problems, an anti-reflective layer formed of a conductive material is suggested. However, the anti-reflective layer formed of the conductive material has a low refractive index, and thus has a limit in preventing (or reducing) the reflection of light. Particularly, because the refractive index of the anti-reflective layer formed of the conductive material decreases rapidly in the long wavelength spectrum, the reflection of the light cannot be effectively prevented (or reduced) in the long wavelength spectrum.

The above information disclosed in this Background section is only for enhancement of understanding of the background of the invention and therefore it may contain information that does not form the prior art that is already known in this country to a person of ordinary skill in the art.

### SUMMARY OF THE INVENTION

An aspect of an embodiment of the present invention is directed toward a solar cell and a method for manufacturing the same having a simple manufacturing method, capable of preventing or (or reducing) damage induced by a high temperature, and having an excellent effect for preventing (or reducing) light reflection.

An exemplary embodiment of the present invention provides a solar cell including a semiconductor substrate, a first electrode, an emitter portion, an anti-reflective layer, and a second electrode. The semiconductor substrate is of a first conductive type, and has a first surface and a second surface facing away from each other. The first electrode is electrically coupled to the first surface of the semiconductor substrate. The emitter portion is of a second conductive type, and is formed adjacent to the second surface of the semiconductor substrate. The anti-reflective layer is on the emitter portion and includes a transparent electrode, and the second electrode is formed on the anti-reflective layer and is electrically connected to the emitter portion through the anti-reflective layer. The anti-reflective layer has a refractive index that is not less than 1.5 for a spectrum ranging from about 400 nm to about 1000 nm, and the anti-reflective layer has a sheet resistance that is not greater than that of the emitter portion.

The sheet resistance of the anti-reflective layer may not be greater than 40 Ω/□.

The anti-reflective layer may include zinc oxide (ZnO).

The anti-reflective layer may further include at least one material selected from the group consisting of indium (In), gallium (Ga), aluminum (Al), fluorine (F), hydrogen (H), and combinations thereof.

The anti-reflective layer may be formed of indium-zinc oxide (IZO).

The second electrode may include silver (Ag).

The solar cell may further include a passivation layer between the emitter portion and the anti-reflective layer. The passivation layer may include amorphous silicon.

The first electrode may include a first electrode portion located on the first surface of the semiconductor substrate to partially cover the first substrate and a second electrode portion located on the first surface of the semiconductor substrate to cover the first electrode portion. The solar cell may further include a rear passivation layer between the first surface of the semiconductor substrate and the second electrode portion, and at a portion where the first electrode portion is not located. The second electrode portion may cover the first electrode portion and the rear passivation layer.

Another exemplary embodiment of the present invention provides preparing a semiconductor substrate of a first conductive type and having a first surface and a second surface facing away from each other, forming an emitter portion of a second conductive type on the second surface of the semiconductor substrate, forming a passivation layer on the first surface of the semiconductor substrate, forming a first electrode layer on the passivation layer, heat-treating the first electrode layer to form a first electrode including a connection part formed by diffusing a material of the passivation layer with a material of the first electrode layer, forming an anti-reflective layer including a transparent electrode on the emitter portion, and forming a second electrode on the anti-reflective layer.

In the heat-treating of the first electrode layer, the heat treatment temperature may be below a eutectic point of the material of the passivation layer and a metal of the first electrode layer.

The method may further include forming a second electrode portion to cover the first electrode portion and the passivation layer, after the forming of the second electrode on the anti-reflective layer.

The forming of the second electrode may include applying a paste for forming the second electrode, the paste including silver or silver oxide, and heat-treating by firing the paste for forming the second electrode at a temperature ranging from about 50 to about 400° C.

The anti-reflective layer may have a refractive index that is not less than 1.5 in a spectrum ranging from about 400 nm to about 1000 nm, and wherein the anti-reflective layer has a sheet resistance that may not be greater than that of the emitter portion. The sheet resistance of the anti-reflective layer may not be greater than 40 Ω/□.

The anti-reflective layer may include zinc oxide. The anti-reflective layer may further include at least one material selected from the group consisting of indium (In), gallium (Ga), aluminum (Al), fluorine (F), hydrogen (H), and combinations thereof. The anti-reflective layer may be formed of indium-zinc oxide (IZO).

According to the solar cell of one exemplary embodiment, the anti-reflective layer is formed of a transparent electrode having a refractive index (e.g., a predetermined refractive index). Therefore, the second electrode can be electrically coupled to the emitter portion without the firing through method, and the reflection of the light can be effectively prevented (or reduced) in the solar spectrum. Accordingly, the manufacturing method of the solar cell can be simplified, and a ratio of light utilization can be improved. As a result, the energy conversion efficiency of the solar cell can be improved.

In addition, the anti-reflective layer has a low sheet resistance (e.g., a predetermined sheet resistance), and the anti-reflective layer acts as an electrode along with the second electrode. Accordingly, the effect of collecting the current can be improved, thereby increasing the energy conversion efficiency of the solar cell.

In the solar cell according to one exemplary embodiment, the first electrode (rear electrode) includes the first electrode portion to be connected to the semiconductor substrate and the second electrode portion substantially collecting the charges. Thus, the energy conversion efficiency of the solar cell can be improved, the solar cell can be thinner, and the manufacturing cost of the solar cell can be reduced.

Since the first electrode portions formed for an electrical connection can be formed with a small area, the rear passivation layer can be formed with a large area. Thus, a recombination of charges is effectively prevented (or reduced). The second electrode portion composed of a material having excellent (or high) electrical conductivity can be wholly formed on the semiconductor substrate. Therefore, the charges can be effectively collected. In addition, the second electrode portion is used as a reflective layer, thereby increasing a ratio of light utilization. Accordingly, the energy conversion efficiency of the solar cell can be further improved.

In the exemplary embodiment, the second electrode portion having excellent (or high) electrical conductivity is wholly formed on the first surface (rear surface) of the semiconductor substrate. As a result, the solar cell can be thin. Further, the manufacturing cost of the solar cell can be reduced.

In the present exemplary embodiment, a plurality of dot electrodes are distributed over the first surface of the semiconductor substrate as the first electrode portions, and thus the second electrode portion can be uniformly connected to the semiconductor substrate. Also, an area of the first passivation layer can be increased (or maximized).

When the first passivation layer is formed of amorphous silicon and the first electrode portion is formed of aluminum, because silicon and aluminum can be diffused at a low temperature, a connecting portion that is electrically connected to the semiconductor substrate can be formed at a low temperature. That is, the first electrode portion of the first electrode can be formed at a low temperature without a firing through process. Accordingly, damage to the solar cell that is induced at a high temperature can be prevented (or reduced).

Since the second electrode is formed by using a paste including silver or silver oxide particles having a diameter of nanometers, the second electrode can be formed by heat treatment at a low temperature without the firing through process. Accordingly, damage to the solar cell that is induced at a high temperature can be prevented (or reduced). In addition, the manufacturing method can be simplified.

When the passivation layer formed on the front surface of the semiconductor substrate is formed of the same (or substantially the same) material as the passivation layer formed on the rear surface of the semiconductor substrate, the passivation layers can be simultaneously formed in the same process. Thus, the manufacturing process can be simplified.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 is a cross-sectional schematic view of a solar cell according to an exemplary embodiment of the present invention.

FIG. 2 is a bottom plan schematic view of the solar cell according to an exemplary embodiment of the present invention.

FIG. 3 is a graph showing refractive indexes of anti-reflective layers, each including indium-tin oxide (ITO), silicon nitride (SiNx), and zinc oxide (ZnO), according to wavelength.

FIG. 4 is a graph showing reflectivity of anti-reflective layers, each including indium-tin oxide (ITO), silicon nitride (SiNx), and zinc oxide (ZnO), according to wavelength.

FIG. 5 is a graph showing an effective lifetime (or lifespan) of electrons according to a thickness of an amorphous silicon layer.

FIG. 6 is a flowchart showing a manufacturing method of a solar cell according to an exemplary embodiment of the present invention.

FIG. 7A to FIG. 7H are cross-sectional schematic views, each showing a step of the manufacturing method of the solar cell according to an exemplary embodiment of the present invention.

### DETAILED DESCRIPTION

In the following detailed description, only certain exemplary embodiments of the present invention have been shown and described, simply by way of illustration. As those skilled in the art would realize, the described embodiments may be modified in various different ways, all without departing from the spirit and scope of the present invention. Accordingly, the drawings and description are to be regarded as illustrative in nature and not restrictive. Like reference numerals designate like elements throughout the specification.

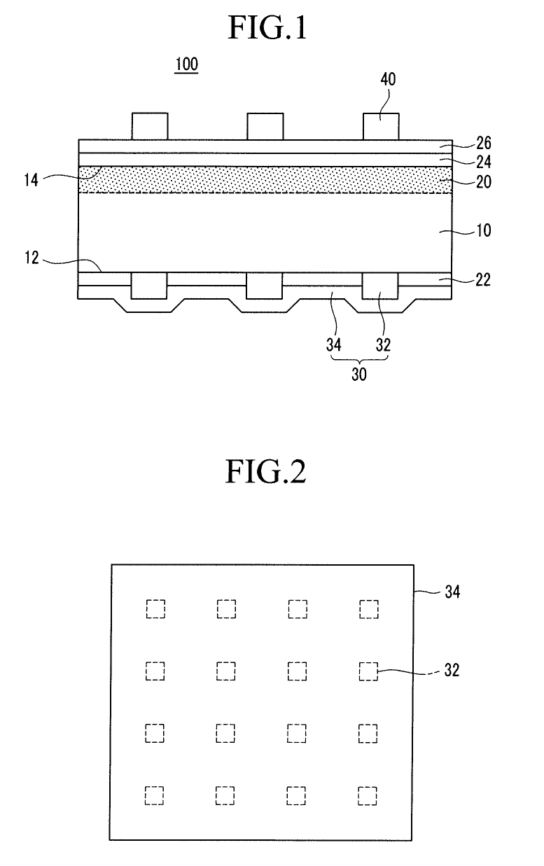

FIG. 1 is a cross-sectional schematic view of a solar cell according to an exemplary embodiment of the present invention, and FIG. 2 is a bottom plan schematic view of the solar cell according to an exemplary embodiment of the present invention.

Referring to FIG. 1, a solar cell 100 of the present exemplary embodiment includes a semiconductor substrate 10, at least one first electrode (hereinafter, “rear electrode”) 30, an emitter portion 20, and at least one second electrode (hereinafter, “front electrode”) 40. The semiconductor substrate 10 has a first surface (hereinafter, “rear surface”) 12 and a second surface (hereinafter, “front surface”) 14 opposite to each other (or facing away from each other). The rear electrode 30 is electrically coupled to the rear surface 12 of the semiconductor substrate 10, the emitter portion 20 is formed adjacent to (or on) the front surface 14 of the semiconductor substrate 10, and the front electrode 40 is electrically coupled to the emitter portion 20.

A first passivation layer (hereinafter, “rear passivation layer”) 22 is formed on the rear surface 12 of the semiconductor substrate 10, and a second passivation layer (hereinafter, “front passivation layer”) 24 and an anti-reflective layer 26 are formed on the emitter portion 20.

Hereinafter, the solar cell 100 will be described in more detail.

In the present exemplary embodiment, the semiconductor substrate 10 is formed of crystalline silicon and is of a first conductive type. The first conductive type is p-type in the present exemplary embodiment. However, the present invention is not limited thereto. Thus, the semiconductor substrate 10 may be of an n-type conductive type, and may be formed of various suitable semiconductor materials other than silicon.

The emitter portion 20 is formed adjacent to the second surface 14 of the semiconductor substrate 10 and is of a second conductive type. The second conductive type is n-type in the present exemplary embodiment. It is sufficient that the second conductive type of the emitter portion 20 is opposite to (or different from) the first conductive type of the semiconductor substrate 10 to form a p-n junction. Thus, in one embodiment, when the semiconductor substrate 10 is of an n-type, the emitter portion 20 is of a p-type.

The emitter portion 20 may be formed by doping a dopant such as phosphorus (P), arsenic (As), and/or antimony (Sb) on the front surface 14 of the semiconductor substrate 10. However, the present invention is not limited thereto. In addition, the emitter portion may be formed as a layer that is separated from the semiconductor substrate and stacked on the semiconductor substrate.

The rear passivation layer 22 and the rear electrode 30, including a first electrode portion 32 and a second electrode portion 34, are formed on the rear surface 12 of the semiconductor substrate 10.

That is, the first electrode portion 32 of the rear electrode 30 is partially formed on the rear surface 12 of the semiconductor substrate 10 (e.g., is formed in a pattern), and the second electrode portion 34 is formed on substantially the entire rear surface 12 of the semiconductor substrate 10 to cover the first electrode portion 32. The rear passivation layer 22 is formed at a portion where the first electrode portion 32 is not formed and between the semiconductor substrate 10 and the second electrode portion 34.

The phrase “the second electrode portion 34 is formed on substantially the entire rear surface 12” refers to the case in which the second electrode portion 34 is not formed on a portion such as the edge (or edge portion) in order to prevent (or reduce) an unwanted short circuit between the emitter portion 20 and the second electrode portion 34 or in order to easily form the second electrode portion 34, as well as the case in which the second electrode portion 34 is formed on the entire rear surface 12.

The rear passivation layer 22 prevents (or reduces) charges from recombining that may be induced at a portion adjacent to the rear surface 12 of the semiconductor substrate 10. That is, a plurality of dangling bonds exist adjacent to the rear surface 12 of the semiconductor substrate 10. If the charges are combined at defects such as the dangling bonds, the charges are lost at the rear surface 12. Therefore, the rear passivation layer 22 is formed on the rear surface 12 of the semiconductor substrate 10 to suppress the recombination of the charges.

The first electrode portion 32 connects the semiconductor substrate 10 to the second electrode portion 34, and the second electrode portion 34 collects charges generated at the semiconductor substrate 10 through the first electrode portion 32.

A connecting portion is formed at at least a portion of the first electrode portion 32 adjacent to the semiconductor substrate 10, and connects the semiconductor substrate 10 to the first electrode portion 32. The connecting portion is formed by diffusion of a material included in the rear passivation layer 22 and a conductive material included in the first electrode portion 32. In the present exemplary embodiment, the entire first electrode portion 32 is formed of the connecting portion. However, the present invention is not limited thereto. For example, the connection portion may be only formed on a portion of the first electrode portion 32 adjacent to the semiconductor substrate 10.

The conductive material of the first electrode portion 32 may be a material that can be easily diffused with the material of the rear passivation layer 22. For example, the rear passivation layer 22 may be formed of amorphous silicon, and the first electrode portions 32 may include aluminum. That is, the connecting portion of the first electrode portion 32 may be formed of a compound of aluminum and silicon.

In the present exemplary embodiment, because it is sufficient that the first electrode portion 32 can be connected to the semiconductor substrate 10, the first electrode portion 32 may be formed with a small area. Thus, the rear passivation layer 22, which is formed at the portion where the first electrode portions 32 are not formed, can be formed with a large area. Accordingly, the effect of preventing (or reducing) charges from recombining can be improved by the rear passivation layer 22.

As shown in FIG. 2, the first electrode portion 32 may include a plurality of dot electrodes (e.g., spare dot electrode) so as to maximize the area of the rear passivation layer 22. In the present exemplary embodiment, the plurality of dot electrodes are distributed over the rear surface 12 of the semiconductor substrate 10, and thus the second electrode portion 34 can be uniformly connected to the semiconductor substrate 10 over the whole semiconductor substrate 10.

A ratio of an area of the first electrode portions 32 to an area of the semiconductor substrate 10 is within a range from about 0.01 to about 0.1 (or from 0.01 to 0.1). In one embodiment, if the ratio is over 0.1, the area of the rear passivation layer 22 decreases and the effect of preventing (or reducing) the charges from recombining may be reduced. In another embodiment, if the ratio is less than 0.01, the first electrode portion 32 may be unstably connected to the semiconductor substrate 10. However, the present invention is not limited thereto and has various suitable ratios. For example, in order to maximize the effect of preventing (or reducing) the charges from recombining, the ratio may be less 0.1.

The second electrode portion 34 may have greater electrical conductivity than that of the first electrode portion 32. That is, the second electrode portion 34 may be formed of a material having specific resistance that is lower than that of the first electrode portion 32. Because the second electrode portion 34 has high electrical conductivity, the second electrode portions 34 can collect the charges excellently (or suitably) and the power consumption can be reduced.

In the present exemplary embodiment, the second electrode portion 34 may be formed of a material having excellent (or light) reflectivity so that the second electrode portion 34 can act as a reflective layer. The second electrode portion 34 reflects the light penetrating the rear passivation layer 22 back to the inside of the solar cell 100, thereby improving a ratio of light utilization.

Considering the electrical conductivity and the reflectivity, the second electrode portion 34 may be formed of silver (Ag), gold (Au), platinum (Pt), and/or copper (Cu). Particularly, when the second electrode portion 34 is formed of silver, the energy conversion efficiency of the solar cell 100 can be improved by the high electrical conductivity and the high reflectivity of silver. In addition, the second electrode portion 34 can be excellently (or suitably) connected to an external terminal by the good soldering properties of silver.

The rear electrode 30 of the present exemplary embodiment includes the first electrode portion 32 connected to the semiconductor substrate 10 and the second electrode portion 34 collecting the charges. Accordingly, the first electrode portion 32 may be formed with a small area, thereby improving the effect of the rear passivation layer 22. The second electrode portion 34 having the high electrical conductivity and the high reflectivity may be formed on the whole area. As a result, the energy conversion efficiency of the solar cell 100 can be improved.

In addition, the rear electrode 30 can be thin because of the excellent electrical conductivity of the second electrode portion 34 in the present exemplary embodiment. Therefore, since the stress induced by a process including a heat treatment can be reduced, the damage of the semiconductor substrate 10 can be reduced. Additionally, the semiconductor substrate 10 can be thin. Thus, the solar cell 100 can be thinner. Further, the manufacturing cost of the solar cell 100 can be decreased because the rear electrode 30 and the semiconductor substrate 10 are thin.

The front passivation layer 24, the anti-reflective layer 26, and the front electrode 40 are sequentially formed on the emitter portion 20.

The front passivation layer 24 prevents (or reduces) the charges from recombining with defects on the front surface 14 of the semiconductor substrate 10. For example, the front passivation layer 24 is formed of amorphous silicon. Since the front passivation layer 24 is formed of the same (or substantially the same) material as the rear passivation layer 22, the front passivation layer 24 and the rear passivation layer 22 can be simultaneously (or concurrently) formed in the same process. Thus, the manufacturing process can be simplified.

The anti-reflective layer 26 prevents (or reduces) a loss of light induced by reflection. The anti-reflective layer 26 may be formed of a transparent electrode including a transparent conductive material.

In the present exemplary embodiment, since the anti-reflective layer 26 is formed of the transparent conductive material, the anti-reflective layer 26 can also act as an electrode for collecting charges, along with the front electrode 40. Sheet resistance of the anti-reflective layer 26 may be the same as or less than that of the emitter portion 20 so that the anti-reflective layer 26 can act as an electrode. The anti-reflective layer 26 cannot act as an electrode if the sheet resistance of the anti-reflective layer 26 is greater than the sheet resistance of the emitter portion 20.

For example, the sheet resistance of the anti-reflective layer 26 may be less than 40 Ω/□, considering that the emitter portion 20 has sheet resistance that is greater than 40 Ω/□. However, the present invention is not limited thereto. For example, the sheet resistance of the emitter portion 20 may increase to over 60 Ω/□ to increase the efficiency of the solar cell, and thus the sheet resistance of the anti-reflective layer 26 can be suitably varied according to the sheet resistance of the emitter portion 20.

The front electrode 40 can be formed on the anti-reflective layer 26 because the front electrode 40 is electrically coupled to the emitter portion 20 by the electrical conductivity of the anti-reflective layer 26. Thus, the firing through process is not necessary, and therefore the manufacturing process can be simplified and the front electrode 40 can be stably formed.

In the present exemplary embodiment, the anti-reflective layer 26 has a refractive index that is greater than 1.5 in the solar spectrum. That is, in the present exemplary embodiment, the refractive index is greater than the value (e.g., 1.5) even in the long wavelength spectrum where the refractive index decreases. Accordingly, the anti-reflective layer 26 can effectively prevent (or reduce) the reflectance of the light in the long wavelength spectrum.

The anti-reflective layer 26 is mainly composed of zinc oxide (ZnO), and further includes indium (In), gallium (Ga), aluminum (Al), fluorine (F), and/or hydrogen (H). For example, the anti-reflective layer 26 may be formed of indium-zinc oxide (IZO).

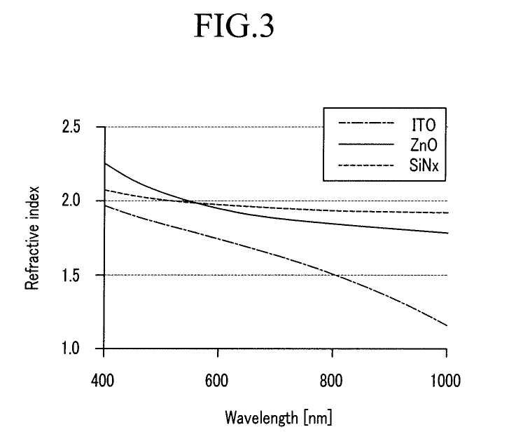

Referring to FIG. 3, it can be seen that the anti-reflective layer including zinc oxide has a refractive index of greater than 1.5 in the solar spectrum. Accordingly, the anti-reflective layer including zinc oxide has a similar refractive index to the conventional anti-reflective layer including silicon nitride (SiNx) in the solar spectrum. On the other hand, although the indium-tin oxide (ITO) is a transparent conductive material, the refractive index of indium-tin oxide decreases rapidly in the long wavelength spectrum, and is less than 1.5 in a wavelength spectrum of greater than 800 nm.

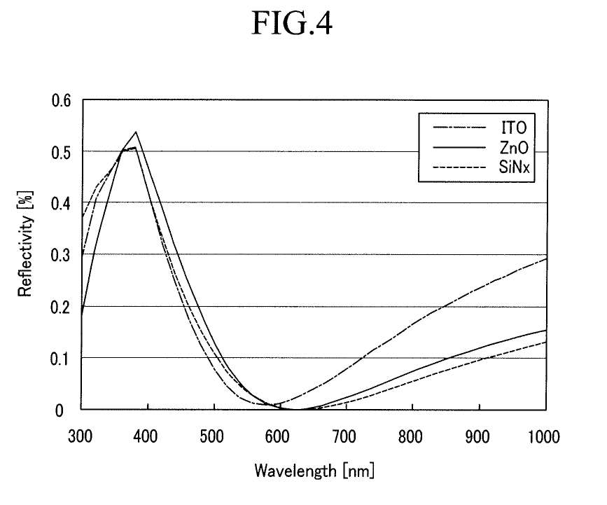

Referring to FIG. 4, the anti-reflective layer including zinc oxide and having the refractive index that is greater than 1.5 in the solar spectrum has very low reflectivity compared with the anti-reflective layer including indium-tin oxide and having a refractive index of less than 1.5 in the wavelength spectrum greater than 800 nm. In the present exemplary embodiment, the reflectivity in the long wavelength can be reduced by limiting the value of the refractive index, thereby increasing a ratio of light utilization.

Accordingly, in the present exemplary embodiment, the refractive index and the sheet resistance of the anti-reflective layer are limited to the range (e.g. a predetermined range), and thus the effect of preventing or reducing the reflectance by the anti-reflective layer can be improved while the anti-reflective layer can act as an electrode. As a result, the efficiency of the solar cell can be improved, and the manufacturing process can be simplified.

The front electrode 40 may have a comb shape having a plurality of stripe electrodes and a connection electrode connecting the plurality of stripe electrodes at one end thereof. The front electrode 40 may be formed of silver (Ag).

Hereinafter, the thickness of the rear passivation layer 22 and/or the thickness of the front passivation layer 24, which is suitable for preventing (or reducing) a recombination of the charges, will be described in a case in which at least one of the rear passivation layer 22 and the front passivation layer 24 is formed of amorphous silicon. The effect of preventing (or reducing) the recombination of the charges, that is, the passivation effect, is estimated by measuring an effective lifetime (or lifespan) of electrons using quasi steady state photo conductance (QSSPC).

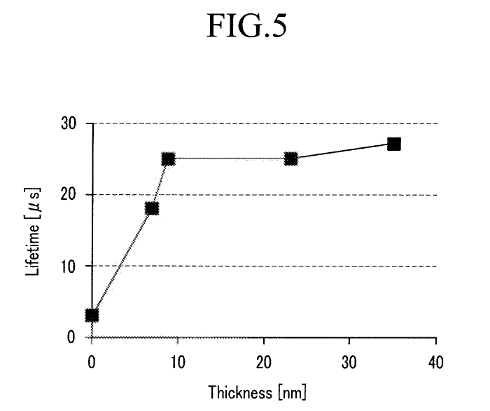

FIG. 5 is a graph showing an effective lifetime (or lifespan) of electrons according to the thickness of an amorphous silicon layer.

To achieve a proper passivation effect, the rear passivation layer 22 and/or the front passivation layer 24, being an amorphous silicon layer, may have a thickness of greater than 1 nm. Referring to FIG. 5, when the thickness of the amorphous silicon layer is greater than about 10 nm, the effective lifetime is excellent (or relatively high). Thus, in one embodiment, the rear and/or front passivation layer 22 or 24 has a thickness that is greater than about 10 nm to increase the passivation effect. When the thickness of the amorphous silicon layer is greater than 100 nm, the manufacturing cost may be increased and the light may be absorbed to the rear and front passivation layers 22 and 24. Thus, the rear passivation layer 22 or the front passivation layer 24 may have a thickness of less than 100 nm.

In one embodiment, considering the effective lifetime and thickness, the rear passivation layer 22 and/or the front passivation 24 has a thickness ranging from about 20 to about 50 nm (or from 20 to 50 nm). However, the present invention is not limited thereto.

When light is incident on the solar cell, a pair of a positive hole and an electron formed by a photoelectric effect are separated, and thus electrons are accumulated on the n-type emitter portion 20 while positive holes are accumulated on the p-type semiconductor substrate 10. The charges are collected by the front and rear electrodes 30 and 40 and flow, and thus the solar cell operates.

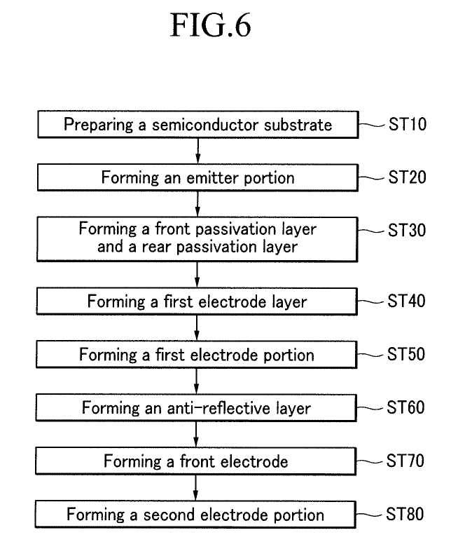

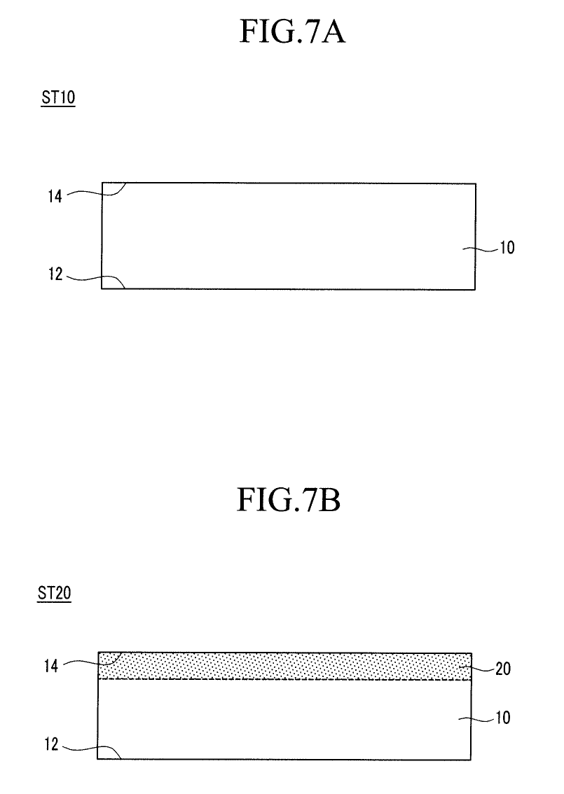

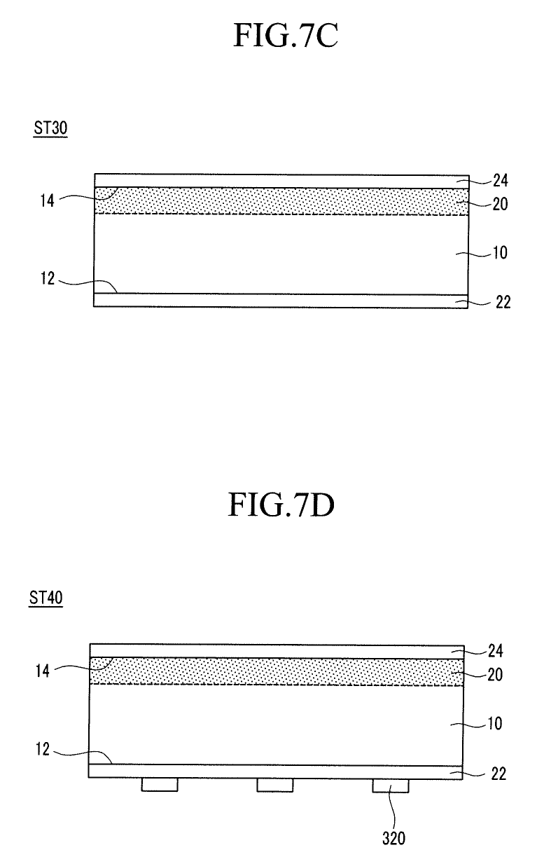

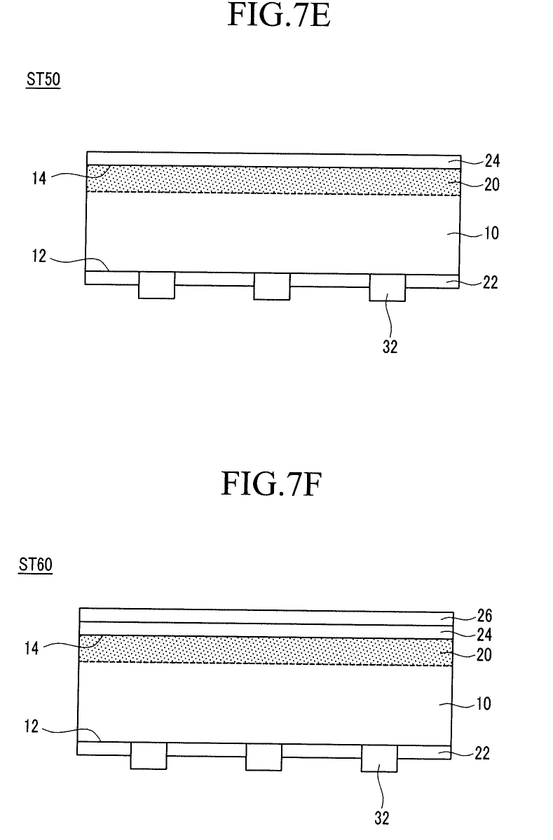

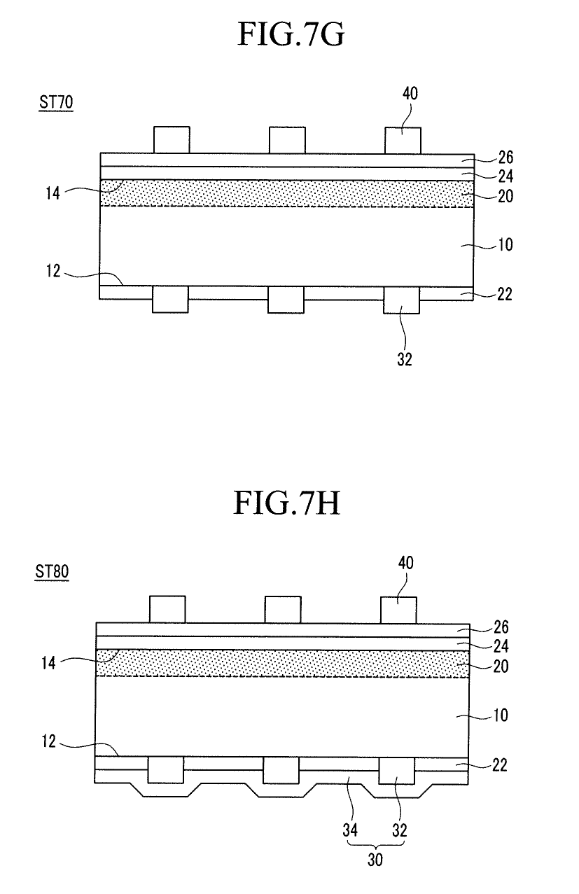

Hereinafter, an exemplary embodiment of a manufacturing method of the solar cell having the above-mentioned structure will be described with reference to FIGS. 6 and 7A to 7H. The exemplary embodiment of the manufacturing method is only for describing the solar cell clearly, and thus the present invention is not limited thereto. Detailed descriptions regarding elements already described above will be omitted.

FIG. 6 is a flowchart showing a manufacturing method of a solar cell according to an exemplary embodiment of the present invention. FIG. 7A to FIG. 7H are cross-sectional schematic views, each showing a step of the manufacturing method of the solar cell according to an exemplary embodiment of the present invention.

Referring to FIG. 6, the manufacturing method of the solar cell according to the present exemplary embodiment includes a step ST10 of preparing a semiconductor substrate, a step ST20 of forming an emitter portion, a step ST30 of forming a front passivation layer and a rear passivation layer, a step ST40 of forming a first electrode layer, a step ST50 of forming a first electrode portion, a step ST60 of forming of an anti-reflective layer, a step ST70 of forming a front electrode, and a step ST80 of forming a second electrode portion.

Each of the steps will be described referring to FIGS. 7A to 7H, along with FIG. 6.

First, as shown in FIG. 7A, in the step ST10 of preparing a semiconductor substrate, a p-type semiconductor substrate 10 formed of silicon is prepared.

Subsequently, as shown in FIG. 7B, in the step ST20 of forming an emitter portion, a dopant such as phosphorus, arsenic, and/or antimony is doped on the front surface 14 of the semiconductor substrate 10 in order to form an n-type emitter portion 20. The doping method may be one or more of various suitable methods, such as a high-temperature diffusion method, a spray method, a screen printing method, and an ion shower method.

For example, phosphoryl chloride (POCl₃) is thermally pyrolyzed in a diffusion furnace, a phosphosilicate glass (PSG) layer is formed on the surface of the semiconductor substrate 10, and phosphorus in the PSG layer is diffused into the semiconductor substrate 10 in order to form the emitter portion 20. Then, the PSG is eliminated with dilute hydrofluoric acid (HF), and a portion where the phosphorus is unnecessarily diffused is removed with an alkaline solution, such as potassium hydroxide (KOH).

However, the present invention is not limited thereto. For example, various suitable dopants and/or doping methods may be used to form the emitter portion 20. Selectively, the emitter portion may be formed as a layer that is separated from the semiconductor substrate and stacked on the front surface of the semiconductor substrate.

Subsequently, as shown in FIG. 7C, in the step ST30 of forming a rear passivation layer and a front passivation layer, the rear and front passivation layers 22 and 24 of amorphous silicon are formed on the rear and front surfaces 12 and 14 of the semiconductor substrate 10, respectively. The rear and front passivation layers 22 and 24 may be formed by plasma enhanced chemical vapor deposition (PECVD).

Subsequently, as shown in FIG. 7D, in the step ST40 of forming a first electrode layer, first electrode layers 320 having dot shapes are formed on the rear surface 12 of the semiconductor substrate 10. The first electrode layers 320 are formed by performing a vacuum plating method and/or a sputtering method in a state in which a mask is in close contact with the semiconductor substrate 10.

Subsequently, as shown in FIG. 7E, in the step ST50 of forming a first electrode portion, a first electrode portion 32 including a connecting portion is formed by a heat treatment. The connecting portion is formed by reciprocal diffusion of silicon included in the rear passivation layer 22 and aluminum included in the first electrode layer 320 (see FIG. 7D). The connecting portion is electrically connected to the semiconductor substrate 10 with a sufficiently low contact resistance.

The heat treatment of the step ST50 can be performed under a suitable gas atmosphere of an inert gas, such as nitrogen and argon, with about 3% hydrogen to prevent (or reduce) oxidation of silicon and aluminum, and at a temperature below the eutectic point of silicon and aluminum. That is, the heat treatment may be performed at a temperature of less than 577° C., which is below the eutectic point of silicon and aluminum.

According to the present exemplary embodiment, the first electrode portion including the connecting portion is formed at a temperature below the eutectic point. Therefore, damage to the solar cell that is generated by heat treatment at a high temperature can be prevented (or reduced).

Subsequently, as shown in FIG. 7F, in the step ST60 of forming an anti-reflective layer, an anti-reflective layer 26 composed of a transparent conductive material is formed on the front passivation layer 24. The anti-reflective layer 26 may be formed by a sputtering method.

As described above, the anti-reflective layer 26 mainly composed of zinc oxide (ZnO), and further includes indium (In), gallium (Ga), aluminum (Al), fluorine (F), and/or hydrogen (H). For example, the anti-reflective layer may be formed of indium-zinc oxide (IZO).

Subsequently, as shown in FIG. 7G, in the step ST70 of forming a front electrode, the front electrode 40 is formed on the anti-reflective layer 26. The front electrode 40 is formed by printing a paste including silver or silver oxide particles having a diameter ranging from several tens to several hundreds of nanometers by screen printing and firing the paste by a heat treatment. Since the paste for forming the front electrode includes silver oxide of a nanometer size, the formed front electrode 40 has specific resistance similar to the specific resistance of silver, that is, 1.6×10⁻⁶ Ω·cm, by firing at a low temperature ranging from about 50° C. to about 400° C. (or from 50° C. to 400° C.).

Subsequently, as shown in FIG. 7H, in the step ST80 of forming a second electrode portion, the second electrode portion 34 is formed to cover the whole first electrode portion 32 and the whole rear passivation layer 22 such that the manufacturing of the rear electrode 30 is completed. The second electrode portion 34 may be formed by depositing silver, platinum, gold, and/or copper using, for example, a vacuum plating method or a sputtering method.

According to the present exemplary embodiment, the heat treatment in the step ST50 of forming the first electrode portions and the step ST70 of forming the front electrode can be performed at a low temperature. Thus, damage that is induced at a high temperature can be prevented (or reduced), and various suitable materials can be applied to the solar cell. For example, a transparent conductive material can be damaged at a high temperature. In the present exemplary embodiment, because the heat treatment is performed at a low temperature, the damage to the anti-reflective layer 26 can be prevented (or reduced).

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A solar cell, comprising:
a semiconductor substrate of a first conductive type, the semiconductor substrate having a first surface and a second surface facing away from each other;
a first electrode electrically coupled to the first surface of the semiconductor substrate;
an emitter portion of a second conductive type, the emitter portion being adjacent to the second surface of the semiconductor substrate;
an anti-reflective layer on the emitter portion and comprising a transparent electrode; and
a second electrode on the anti-reflective layer and electrically coupled to the emitter portion through the anti-reflective layer,
wherein the anti-reflective layer has a refractive index that is not less than 1.5 in a spectrum ranging from about 400 nm to about 1000 nm, and
wherein the anti-reflective layer has a sheet resistance that is not greater than that of the emitter portion.

2. The solar cell of claim 1, wherein
the sheet resistance of the anti-reflective layer is not greater than 40 Ω/□.

3. The solar cell of claim 1, wherein
the anti-reflective layer comprises zinc oxide (ZnO).

4. The solar cell of claim 3, wherein
the anti-reflective layer further comprises at least one material selected from the group consisting of indium (In), gallium (Ga), aluminum (Al), fluorine (F), hydrogen (H), and combinations thereof.

5. The solar cell of claim 4, wherein
the anti-reflective layer comprises indium-zinc oxide (IZO).

6. The solar cell of claim 1, wherein
the second electrode comprises silver (Ag).

7. The solar cell of claim 1, further comprising
a passivation layer between the emitter portion and the anti-reflective layer,
wherein the passivation layer comprises amorphous silicon.

8. The solar cell of claim 1, wherein
the first electrode comprises a first electrode portion located on the first surface of the semiconductor substrate to partially cover the first surface and a second electrode portion located on the first surface of the semiconductor substrate to cover the first electrode portion.

9. The solar cell of claim 8, further comprising
a rear passivation layer between the first surface of the semiconductor substrate and the second electrode portion and at a portion where the first electrode portion is not located,
wherein the second electrode portion covers the first electrode portion and the rear passivation layer.

10. A solar cell, comprising:
a semiconductor substrate of a first conductive type, the semiconductor substrate having a first surface and a second surface facing away from each other;
a first electrode electrically coupled to the first surface of the semiconductor substrate;
an emitter portion of a second conductive type, the emitter portion being adjacent to the second surface of the semiconductor substrate; and
an anti-reflective layer on the emitter portion and comprising a transparent electrode including zinc oxide; and
a second electrode on the anti-reflective layer and electrically coupled to the emitter portion through the anti-reflective layer.

11. A method for manufacturing a solar cell, comprising:
preparing a semiconductor substrate of a first conductive type, the semiconductor substrate having a first surface and a second surface facing away from each other;
forming an emitter portion of a second conductive type on the second surface of the semiconductor substrate;
forming a passivation layer on the first surface of the semiconductor substrate;
forming a first electrode layer on the passivation layer;
heat-treating the first electrode layer to form a first electrode comprising a connection part formed by diffusing a material of the passivation layer with a material of the first electrode layer;
forming an anti-reflective layer comprising a transparent electrode on the emitter portion; and
forming a second electrode on the anti-reflective layer.

12. The method of claim 11, wherein,
in the heat-treating of the first electrode layer, the heat treatment temperature is below a eutectic point of the material of the passivation layer and a metal of the first electrode layer.

13. The method of claim 11, further comprising
forming a second electrode portion to cover the first electrode portion and the passivation layer, after the forming the second electrode on the anti-reflective layer.

14. The method of claim 11, wherein
the forming of the second electrode comprises applying a paste for forming the second electrode, the paste comprising silver or silver oxide, and heat-treating by firing the paste for forming the second electrode at a temperature ranging from about 50 to about 400° C.

15. The method of claim 11, wherein
the anti-reflective layer has a refractive index of not less than 1.5 in a spectrum ranging from about 400 nm to about 1000 nm, and
wherein the anti-reflective layer has a sheet resistance that is not greater than that of the emitter portion.

16. The method of claim 15, wherein
the sheet resistance of the anti-reflective layer is not greater than 40 Ω/□.

17. The method of claim 11, wherein
the anti-reflective layer comprises zinc oxide.

18. The method of claim 17, wherein
the anti-reflective layer further comprises at least one material selected from the group consisting of indium (In), gallium (Ga), aluminum (Al), fluorine (F), hydrogen (H), and combinations thereof.

19. The method of claim 18, wherein
the anti-reflective layer comprises indium-zinc oxide (IZO).
